(19) United States
(12) Patent Application Publication
(10) Pub. No.: US 2013/0000546 A1
(43) Pub. Date: Jan. 3, 2013

(54) METHOD OF VAPOR PHASE EPITAXY AND VAPOR PHASE EPITAXY DEVICE

(76) Inventors: Kunihiko SUZUKI, Sunto-gun (JP); Shinichi Mitani, Numazu-shi (JP)

(21) Appl. No.: 13/535,191

(22) Filed: Jun. 27, 2012

(30) Foreign Application Priority Data
Jun. 30, 2011 (JP) 2011-145654

(51) Int. Cl. C30B 25/16; C30B 25/10

(52) U.S. Cl. 117/86; 117/85; 118/712; 118/708

(57) ABSTRACT

A method of vapor phase epitaxy that is one embodiment of the present invention characteristically includes loading a wafer in a reaction chamber and mounting the wafer on a supporting section; heating the wafer by a heater provided under the supporting section; performing deposition on the wafer by supplying a process gas onto the wafer while rotating the wafer; detecting a temperature distribution at least in a circumferential direction at a peripheral edge section of the wafer; and determining a presence/absence of adhesion between the wafer and the supporting section based on the detected temperature distribution.

### CROSS-REFERENCE TO RELATED APPLICATION

This application is based upon and claims the benefit of priority from the prior Japanese Patent Application No. 2011-145654 filed on Jun. 30, 2011, the entire contents of which are incorporated herein by reference.

### BACKGROUND

The present invention relates to a method of vapor phase epitaxy and a vapor phase epitaxy device used for example in performing deposition by supplying a reaction gas to a surface of a semiconductor wafer while heating the semiconductor wafer from a back surface thereof.

In recent years, a high quality such as improved thickness uniformity has been required in addition to high productivity in a deposition process accompanied with a request for cost reduction and high performance of a semiconductor device.

A single wafer type of vapor phase epitaxy device is used to meet such a request. In the single wafer type of vapor phase epitaxy device, for example, deposition is performed on a wafer by a back side heating method in which a process gas is supplied while rotating a wafer at a high speed of 900 rpm or more in a reaction chamber and the wafer is heated from a back surface thereof using a heater.

In the deposition process as above, products are deposited not only on the wafer but also on a susceptor that is a supporting member for the wafer. When the products are deposited between the wafer and the susceptor, the wafer adheres to the susceptor, in which case the wafer may be lifted in a state with the susceptor being adhered thereto upon lifting the wafer by a push-up pin to unload the wafer. Further, if the wafer or the susceptor is damaged upon lifting the wafer or upon mounting it on a robot hand, there is a problem that an operation for removal performed by reducing a temperature in a reaction chamber becomes necessary, whereby an yield and a throughput are decreased.

### SUMMARY

A method of vapor phase epitaxy that is one embodiment of the present invention characteristically includes loading a wafer in a reaction chamber and mounting the wafer on a supporting section; heating the wafer by a heater provided under the supporting section; performing deposition on the wafer by supplying a process gas onto the wafer while rotating the wafer; detecting a temperature distribution at least in a circumferential direction at a peripheral edge section of the wafer; and determining a presence/absence of adhesion between the wafer and the supporting section based on the detected temperature distribution.

A vapor phase epitaxy device that is one embodiment of the present invention characteristically includes a reaction chamber into which a wafer is loaded; a supporting section on which the wafer is mounted in the reaction chamber; a rotation drive control section that rotates the wafer together with the supporting section; a gas supply section that supplies a process gas onto the wafer; a gas discharge section that discharges gases from the reaction chamber; a heater provided under the supporting section and that heats the wafer to a predetermined temperature; a temperature detecting section that detects a temperature distribution at least in a circumferential direction at a peripheral edge section of the wafer; and a calculation processing section that determines a presence/absence of adhesion between the wafer and the supporting section based on the temperature distribution detected by the temperature detecting section.

### BRIEF DESCRIPTION OF THE DRAWINGS

FIG. 1 is a cross sectional diagram showing a vapor phase epitaxy device according to a first embodiment of the present invention;

FIG. 2 is a flow chart showing a specific example of a process by the vapor phase epitaxy device shown in FIG. 1;

FIG. 3 is a partial cross sectional diagram showing a state between a wafer and a susceptor in a case of determining that an adhesion is absent in the vapor phase epitaxy device shown in FIG. 1;

FIG. 4 is a diagram showing a temperature distribution in a circumferential direction of a peripheral edge section of the wafer in the state of FIG. 3;

FIG. 5A is a partial cross sectional diagram showing the state between the wafer and the susceptor in a case of determining that the adhesion is present in the vapor phase epitaxy device shown in FIG. 1;

FIG. 5B is a plan diagram showing the state between the wafer and the susceptor in the case of determining that the adhesion is present in the vapor phase epitaxy device shown in FIG. 1;

FIG. 6 is a diagram showing a temperature distribution in the circumferential direction of the peripheral edge section of the wafer in the state of FIG. 5A and FIG. 5B;

FIG. 7A is a diagram showing temperature distributions before a deposition and after the deposition as detected in a vapor phase epitaxy device according to a second embodiment of the present invention;

FIG. 7B is a diagram showing the temperature distributions before the deposition and after the deposition as detected in the vapor phase epitaxy device according to the second embodiment of the present invention; and

FIG. 8 is a diagram showing temperature distributions in a diameter direction at predetermined phases respectively in a case of determining that an adhesion is present at an entire circumference of a wafer w and a case of determining that the adhesion is absent thereat in a vapor phase epitaxy device according to a third embodiment of the present invention.

### DETAILED DESCRIPTION

Reference will now be made in detail to the present embodiment of the invention, an example of which is illustrated in the accompanying drawings.

### First Embodiment

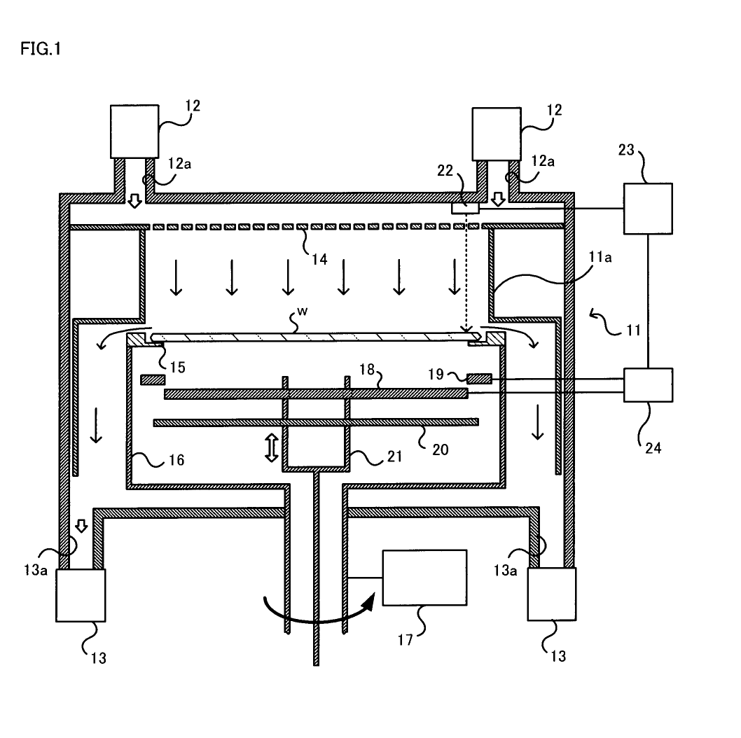

FIG. 1 shows a cross sectional diagram of a vapor phase epitaxy device of the present embodiment. As shown in FIG. 1, in a reaction chamber 11 in which a wafer w is to undergo a deposition process, a quartz cover 11a is provided as needed so as to cover inner walls thereof.

A gas supply inlet 12a connected to a gas supplying section 12 for supplying a process gas including a source gas and a carrier gas is provided at an upper portion of the reaction chamber 11. Further, at a lower portion of the reaction chamber 11, gas discharge outlets 13a connected to gas discharging sections 13 for discharging gases and controlling a pressure inside the reaction chamber 11 at a constant value (for example, an ordinary pressure) are provided for example at two positions.

A rectifying plate 14 having minute through holes for rectifying and supplying the supplied process gas is provided at under the gas supply inlet 12a.

Further, a susceptor 15 for example formed of SiC that is a supporting section for mounting the wafer w is provided under the rectifying plate 14. The susceptor 15 is mounted on a ring 16 that is a rotating member. The ring 16 is connected to a rotation drive control section 17 configured of a motor and the like via a rotation shaft that rotates the wafer w at a predetermined rotational speed.

A heater configured of an inner heater 18 and an outer heater 19 for example formed of SiC for heating the wafer w is provided inside the ring 16, and is connected to a temperature control section 24 that controls the inner heater 18 and the outer heater 19 respectively to be at a predetermined temperature at a predetermined temperature changing speed. Further, a disc-shaped reflector 20 for reflecting a downward heat from the inner heater 18 and the outer heater 19 and effectively heating the wafer w is provided. Further, a push-up pin 21 that supports a lower surface of the wafer w and moves the wafer w up and down is provided so as to penetrate the inner heater 18 and the reflector 20.

A radiation thermometer 22 that is a temperature detecting section for detecting a temperature distribution at a peripheral edge section of the wafer w is provided at the upper portion of the reaction chamber 11, and is connected to a calculation processing section 23. By using such a semiconductor manufacturing device, an Si epitaxial film is formed for example on the wafer w of φ200 mm.

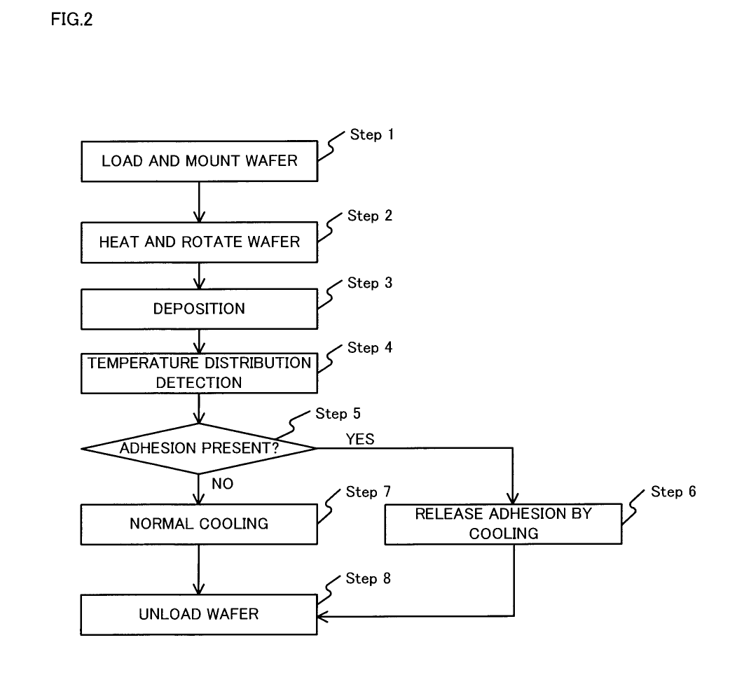

FIG. 2 is a flow chart showing a specific example of a process by the vapor phase epitaxy device shown in FIG. 1. Firstly, the wafer w is loaded into the reaction chamber 11 by a robot hand (not shown) and the like and is mounted on the push-up pin 21, and the wafer w is mounted on the susceptor 15 by lowering the push-up pin 21 (Step 1).

Next, the wafer w is heated for example to be at 1100° C. by causing the inner heater 18 and the outer heater 19 respectively for example to be at 1500 to 1600° C. by the temperature control section, and the wafer w is rotated for example at 900 rpm by the rotation drive control section 17 (Step 2).

Next, the process gas whose flow rate is controlled by the gas supply control section 12 and mixed is supplied onto the wafer w in a rectified state through the rectifying plate 14. The process gas has dichlorosilane (SiH₂Cl₂) as a source gas diluted to a predetermined concentration (for example, 2.5%) by a diluent gas such as an H₂ gas, for example, and is supplied for example at 50 SLM.

On the other hand, a discharge gas formed of the excessive process gas, reaction by-products, and the like is discharged from the gas discharging openings 13a through the gas discharging sections 13, and the pressure inside the reaction chamber 11 is controlled to be constant (for example, the ordinary pressure). Accordingly, the Si epitaxial film with a predetermined film thickness is formed on the wafer w (Step 3).

Next, for the wafer w onto which the Si epitaxial film has been formed, a temperature distribution in the circumferential direction at the peripheral edge section of the wafer w is detected by measuring a temperature at predetermined positions of the peripheral edge section of the wafer w (for example, with a distance from a wafer edge of 5 mm) by the radiation thermometer 22 while rotating the wafer w (Step 4). Note that, the measurement is not limited to one cycle; an accuracy of the temperature distribution can further be improved by performing the measurement for two cycles or more and calculating an average value.

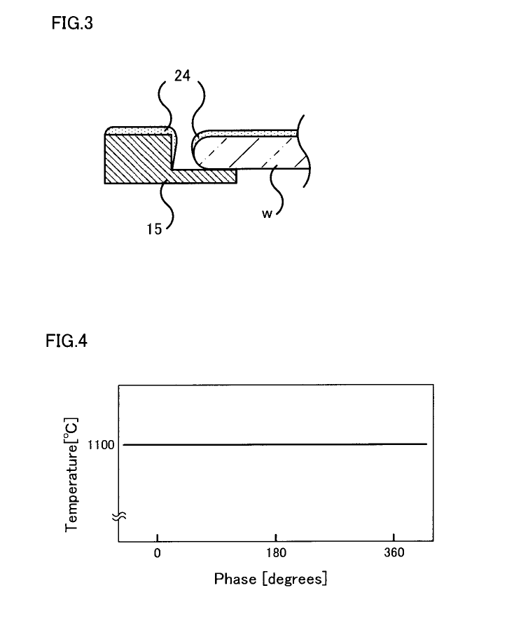

Next, in the calculation processing section 23, a presence/absence of adhesion between the peripheral edge section of the wafer w and the susceptor 15 is determined based on the temperature distribution detected in Step 4 (Step 5). Hereinafter, the determination on the presence/absence of the adhesion will be explained in detail with reference to FIG. 3 to FIG. 6. FIG. 3 is a partial cross sectional diagram showing a state between the wafer w and the susceptor 15 in a case of determining in the vapor phase epitaxy device shown in FIG. 1 that the adhesion is absent, and FIG. 4 is a diagram showing the temperature distribution in the circumferential direction at the peripheral edge section of the wafer w in the state of FIG. 3. As shown in FIG. 3, if the adhesion by deposits 24 between the wafer w and the susceptor 15 is absent, no significant fluctuation can be seen in the temperature distribution in the circumferential direction at the peripheral edge section of the wafer w, as shown in FIG. 4. Accordingly, in such a case, it is determined that no adhesion is present between the wafer w and the susceptor 15.

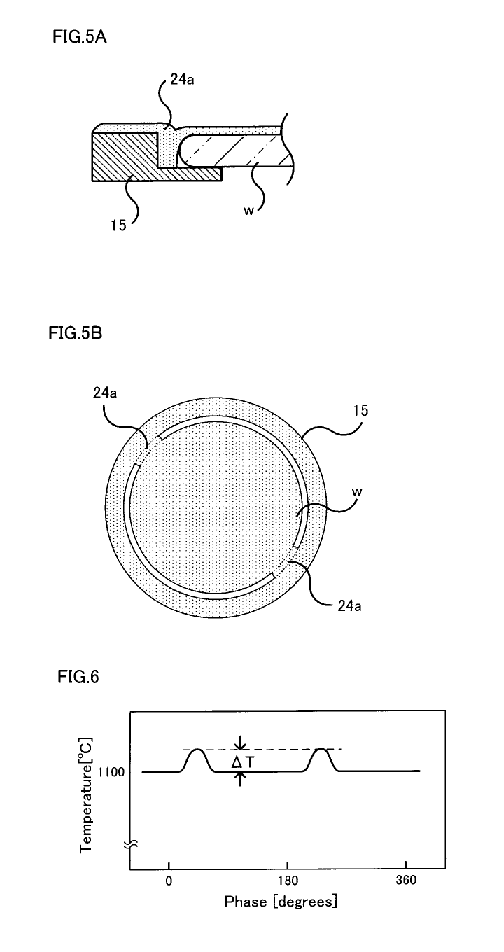

Contrary to this, FIG. 5A and FIG. 5B are respectively a partial cross sectional diagram and a plan diagram showing the state between the wafer w and the susceptor 15 in a case of determining in the vapor phase epitaxy device shown in FIG. 1 that the adhesion is present. Further, FIG. 6 is a diagram showing the temperature distribution in the circumferential direction at the peripheral edge section of the wafer w in the state of FIG. 5A and FIG. 5B. As shown in FIG. 5A and FIG. 5B, if an adhered portion 24a by the deposits 24 is present at a part of the wafer w, the temperature rises at the adhered portion 24a, as shown in FIG. 6.

Accordingly, if the fluctuation in the temperature (ΔT=T(max)−T(min)) exceeds a predetermined value (for example, 5° C.), it is determined in the calculation processing section 23 that the adhesion is present between the wafer w and the susceptor 15 (Step 5: YES). In this case, the wafer w is cooled to a temperature (for example, 500° C.) lower than a regular wafer unload temperature (for example, 800° C.), and the adhered state with the susceptor 15 is released by a contracture difference caused by a difference in coefficients of thermal expansion between the wafer w formed of Si and the susceptor 15 formed of SiC (Step 6).

Then, the wafer w whose adhered state with the susceptor 15 has been released is lifted by the push-up pin 21, and thereafter is unloaded from the reaction chamber 11 by the robot hand and the like (Step 8).

On the other hand, if the temperature increase is within the predetermined value (for example, 5° C.), it is determined in the calculation processing section 23 that the adhesion is absent between the wafer w and the susceptor 15 (Step 5: NO). In this case, the wafer w is cooled to the regular wafer unload temperature (for example, 800° C.) (Step 7), and the wafer is lifted by the push-up pin 21, and is unloaded from the reaction chamber 11 by the robot hand and the like (Step 8).

As described, according to the present embodiment, upon performing the deposition, even in the case of having the adhesion between the wafer w and the susceptor 15, the adhesion can be detected, and the wafer w can be unloaded after having released the adhesion. Due to this, the operation for releasing the adhesion can be performed only when it is necessary. That is, although the temperature reduction for example to 500° C. for releasing the adhesion had generally been performed for an entire lot including the adhesion, herein the operation for releasing the adhesion is performed only on the ones to which the adhesion has been detected. By performing the control as described, about two minutes of time loss caused for each wafer in connection to the temperature reduction and temperature increase can be omitted. Accordingly, damages to the wafer and the susceptor 15 can be suppressed, and the decrease in the yield and throughput can be suppressed.

### Second Embodiment

In the present embodiment, although a vapor phase epitaxy device similar to the first embodiment is used, the temperature distribution at the peripheral edge section of the wafer before the deposition is detected in addition to the temperature distribution after the deposition.

That is, similar to the first embodiment, after the wafer w is loaded in the reaction chamber 11 and is mounted on the susceptor 15, the wafer w is heated for example to be at 1100° C., and the wafer w is rotated for example at 900 rpm by the rotation drive control section 17.

Then, before the process gas is supplied, the temperature distribution at the peripheral edge section of the wafer w is detected by measuring the temperature at the predetermined positions of the peripheral edge section of the wafer w (for example, with the distance from the wafer edge of 5 mm) by the radiation thermometer 22 while rotating the wafer w.

Further, similar to the first embodiment, the process gas is supplied onto the wafer w at the predetermined concentration and the predetermined flow rate, and the Si epitaxial film with the predetermined film thickness is formed on the wafer w. Then, for the wafer w onto which the Si epitaxial film has been formed, the temperature distribution in the circumferential direction at the peripheral edge section of the wafer w is similarly detected.

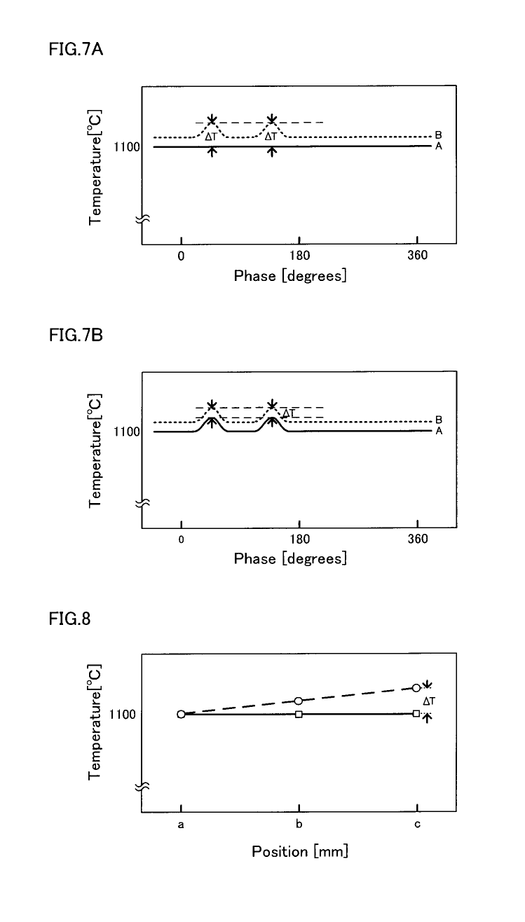

FIG. 7A and FIG. 7B show the temperature distributions before the deposition and after the deposition in the vapor phase epitaxy device in the present embodiment. In FIG. 7A and FIG. 7B, solid lines show a temperature distribution A before the deposition, and dotted lines show temperature distribution B after the deposition.

As shown in FIG. 7A, if the temperature increase exceeds the predetermined value (for example, 5° C.), it is determined that the adhesion is present between the wafer w and the susceptor 15. Then, similar to the first embodiment, cooling is performed to the lower temperature (for example, 500° C.) than the regular wafer unload temperature, and after the adhered state having been released, the wafer is lifted by the push-up pin 21, and is unloaded from the reaction chamber 11 by the robot hand.

On the other hand, as shown in FIG. 7B, even at the same temperature, if there are temperature variations to begin with in the circumferential direction of the wafer w, it is determined that the adhesion is absent if the temperature increase before and after the deposition (ΔT=Tθi (after)−Tθi (initial)) is within the predetermined value (for example, 5° C.). In this case, similar to the first embodiment, the wafer w is cooled to the predetermined temperature (for example, 800° C.), and the wafer w is lifted by the push-up pin 21 and is unloaded from the reaction chamber 11 by the robot hand.

As described, according to the present embodiment, even in the case where the temperature variations are present to begin with in the circumferential direction of the wafer w, the operation to release the adhesion can be performed only when it is necessary by more accurately detecting the adhesion upon the deposition, and taking the wafer w out after having released the adhesion; thus, the time loss can be omitted similar to the first embodiment. Accordingly, the damages to the wafer and the susceptor can be suppressed, and the decrease in the yield and throughput can be suppressed.

### Third Embodiment

Although the vapor phase epitaxy device similar to the first embodiment is used in the present embodiment, it detects the temperature difference of the peripheral edge section of the wafer also in a diameter direction.

That is, similar to the first embodiment, after the wafer w is loaded in the reaction chamber 11 and is mounted on the susceptor 15, the wafer w is heated for example to be at 1100° C., and the wafer w is rotated for example at 900 rpm by the rotation drive control section 17.

Further, similar to the first embodiment, the process gas is supplied onto the wafer w at the predetermined concentration and the predetermined flow rate, and the Si epitaxial film with the predetermined film thickness is formed on the wafer w. Then, for the wafer w onto which the Si epitaxial film has been formed, as shown in FIG. 8, and similar to the first embodiment, a temperature at a position a having the distance from the wafer edge for example of 15 mm is detected by the radiation thermometer 22.

Similarly, a measurement position by the radiation thermometer 22 is changed to an outer circumferential side, and a temperature at a position b having the distance from the wafer edge of 10 mm and a temperature at a position c having the distance from the wafer edge of 5 mm are detected.

FIG. 8 shows the temperature distributions in the diameter direction at predetermined phases (positions in the circumferential direction) in a case of no adhesion at an entire periphery of the wafer w (solid line) and a case of having the adhesion (dotted line). As shown in FIG. 8, it can be understood that, in the case of having the adhesion, the temperature increase at the outer circumferential side becomes larger, whereas in the case of no adhesion, the fluctuation in the temperature is suppressed. Thus, it is determined that the adhesion is present if the temperature increase toward the outer circumferential side (ΔT=Tθi(outer)−Tθi(inner)) is within the predetermined value (for example, 5° C.). In this case, similar to the first embodiment, after the adhered state is released, the wafer w is lifted by the push-up pin 21 and is unloaded from the reaction chamber 11 by the robot hand.

On the other hand, if the temperature increase is within the predetermined value (for example 5° C.), it is determined that the adhesion is absent, and similar to the first embodiment, the wafer w is cooled, and the wafer w is lifted by the push-up pin 21 and is unloaded from the reaction chamber 11 by the robot hand.

As described, according to the present embodiment, even in the case where the adhesion with the susceptor 15 is present at an entire outer circumferential surface of the wafer w, the adhesion upon the deposition can be detected and the wafer w can be unloaded after having released the adhesion by detecting the temperature distribution in the diameter direction, thus, the time loss can be omitted similar to the first embodiment. Accordingly, the operation for releasing the adhesion can be performed only when it is necessary, the damages to the wafer w and the susceptor 15 can be suppressed, and the decrease in the yield and throughput can be suppressed.

Note that, in the present embodiment, although only the temperature distribution after the deposition has been detected, by also detecting the temperature distribution before the deposition similar to the second embodiment, the adhesion upon the deposition can more accurately be detected even in the case of having the temperature variations to begin with in the circumferential direction of the wafer w.

In these embodiments, although the wafer w formed of Si and the susceptor 15 formed of SiC are used, there is no limitation regarding combinations thereof. Any combination is allowable so long as a difference in coefficients of thermal expansion resides between the wafer w and the susceptor 15, so other than the above, for example, a combination of the wafer formed of SiC and the susceptor 15 formed of TaC may be used.

Further, in these embodiments, although the presence/absence of the adhesion is determined by the temperature differences, the presence/absence of the adhesion may be determined by a deviation of the temperatures or the temperature increases. Such a deviation can be calculated from the following formula for example in the example of the second embodiment. It is determined that the adhesion is present between the wafer w and the susceptor 15 if the deviation exceeds the predetermined value.

$$( T θ i ( after ) - T θ i ( initial ) ) / ( 1 / n \times {\sum }_{i = 1}^{n} ( T θ i ( after ) - T θ i ( initial ) ) )$$

Further, in these embodiments, although the presence/absence of the adhesion is determined and the operation for releasing the adhesion is performed in the presence of the adhesion, they are not limited to being used in the determination on whether the releasing operation is necessary or not. For example, information regarding the presence/absence of the adhesion may be stored as history information of the wafer w in the calculation processing section 23 or an externally provided memory. Accordingly, by being stored as the history information of the wafer w, for example, for the wafer to which the adhesion had been present, an internal warpage thereof is assumed to have enlarged due to the operation for releasing the adhesion; thus, for the wafer w as above, a test accuracy thereof can be improved by conducting a reexamination of a wafer state and the like.

According to these embodiments, it becomes possible to stably form films such as the epitaxial film on the semiconductor wafer w at a high productivity. Further, in addition to an improvement in a wafer yield, improving a yield of a semiconductor device to be formed through an element forming step and an element separating step and stabilizing an element performance also become possible. By being adapted especially to an epitaxial forming step for a power semiconductor device such as a power MOSFET, IGBT, and the like in which a thick film growth of 100 μm or more is required for an N type base region, a P type base region, an insulating isolation region and the like, it becomes possible to achieve a satisfactory element performance.

In these embodiments, although examples of forming the Si epitaxial film have been exemplified, other than the above, for example, an adaptation to an epitaxial layer of compound semiconductors such as GaN, GaAlAs, InGaAs, SiC, and the like, an amorphous layer thereof, or a polycrystal layer is also possible. Further, an adaptation to deposition of an insulation film such as SiO₂ layer, Si₃N₄ layer and the like is also possible. Further, the teachings herein may be carried out with various modifications thereto within a scope that does not go beyond a gist thereof.

What is claimed is:

1. A method of vapor phase epitaxy comprising:
loading a wafer in a reaction chamber and mounting the wafer on a supporting section;
heating the wafer by a heater provided under the supporting section;
performing deposition on the wafer by supplying a process gas onto the wafer while rotating the wafer;
detecting a temperature distribution at least in a circumferential direction at a peripheral edge section of the wafer; and
determining a presence/absence of adhesion between the wafer and the supporting section based on the detected temperature distribution.

2. The method of vapor phase epitaxy according to claim 1,
wherein the temperature distributions at least in the circumferential direction at the peripheral edge section of the wafer before and after the deposition are detected, and
the presence/absence of the adhesion between the wafer and the supporting section is determined based on the detected temperature distributions before and after the deposition.

3. The method of vapor phase epitaxy according to claim 1,
wherein the temperature distributions include the temperature distribution in the circumferential direction and the temperature distribution in a diameter direction at the peripheral edge section of the wafer.

4. The method of vapor phase epitaxy according to claim 1, further comprising:
storing determined information regarding the presence/absence of the adhesion as history information of the wafer.

5. The method of vapor phase epitaxy according to claim 1,
wherein the determination that the adhesion is present between the wafer and the supporting section is made when a difference between a maximum value and a minimum value in each of the detected temperature distributions exceeds a predetermined value.

6. The method of vapor phase epitaxy according to claim 1,
wherein the determination that the adhesion is present between the wafer and the supporting section is made when a deviation of the temperatures or the temperature increases exceeds a predetermined value.

7. The method of vapor phase epitaxy according to claim 1, further comprising:
cooling the wafer to a temperature lower than a regular wafer unload temperature when it is determined that the adhesion is present; and
releasing the adhered state with the supporting section.

8. The method of vapor phase epitaxy according to claim 7,
wherein the wafer whose adhered state with the supporting section has been released is lifted by the push-up pin, and thereafter is unloaded from the reaction chamber.

9. The method of vapor phase epitaxy according to claim 1, further comprising:
cooling the wafer to a regular temperature to be unloaded when it is determined that the adhesion is absent; and
unloading the wafer from the reaction chamber after the wafer is lifted by the push-up pin.

10. A method of vapor phase epitaxy comprising:
loading a wafer in a reaction chamber and mounting the wafer on a supporting section;
heating the wafer by a heater provided under the supporting section;
performing deposition on the wafer by supplying a process gas onto the wafer while rotating the wafer;
detecting a temperature distribution in the circumferential direction and a diameter direction at the peripheral edge section of the wafer;
determining a presence/absence of adhesion between the wafer and the supporting section based on a difference between a maximum value and a minimum value in each of the detected temperature distributions; and
storing determined information regarding the presence/absence of the adhesion as history information of the wafer.

11. A vapor phase epitaxy device comprising:
a reaction chamber into which a wafer is loaded;
a supporting section on which the wafer is mounted in the reaction chamber;
a rotation drive control section that rotates the wafer together with the supporting section;
a gas supply section that supplies a process gas onto the wafer;
a gas discharge section that discharges gases from the reaction chamber;
a heater provided under the supporting section and that heats the wafer to a predetermined temperature;
a temperature detecting section that detects a temperature distribution at least in a circumferential direction at a peripheral edge section of the wafer; and
a calculation processing section that determines a presence/absence of adhesion between the wafer and the supporting section based on the temperature distribution detected by the temperature detecting section.

12. The vapor phase epitaxy device according to claim 11,
wherein the temperature detecting section detects the temperature distributions at least in the circumferential direction at the peripheral edge section of the wafer before and after the deposition; and
the calculation processing section determines the presence/absence of the adhesion between the wafer and the supporting section based on the detected temperature distributions detected by the temperature detecting section before and after the deposition.

13. The vapor phase epitaxy device according to claim 12,
wherein the temperature distributions include the temperature distribution in the circumferential direction and the temperature distribution in a diameter direction at the peripheral edge section of the wafer.

14. The vapor phase epitaxy device according to claim 13,
wherein the calculation processing section stores determined information regarding the presence/absence of the adhesion as history information of the wafer.

15. The vapor phase epitaxy device according to claim 14,
wherein the calculation processing section determines that the adhesion is present between the wafer and the supporting section when a difference between a maximum value and a minimum value in each of the detected temperature distributions exceeds a predetermined value.

16. The vapor phase epitaxy device according to claim 11,
wherein the calculation processing section determines that the adhesion is present between the wafer and the supporting section when a deviation of the temperatures or the temperature increases exceeds a predetermined value.

17. The vapor phase epitaxy device according to claim 11, further comprising:
a temperature control section that controls the heating by the heater.

18. The vapor phase epitaxy device according to claim 17,
wherein the temperature control section controls the heating by the heater so that the temperature of the wafer is lower than a regular wafer unload temperature when it is determined that the adhesion is present.

19. The vapor phase epitaxy device according to claim 11, further comprising:
a push-up pin that lifts the wafer.

20. A vapor phase epitaxy device comprising:
a reaction chamber into which a wafer is loaded;
a susceptor on which the wafer is mounted in the reaction chamber;
a rotation drive control section that rotates the wafer together with the susceptor;
a gas supply section that supplies a process gas onto the wafer;
a gas discharge section that discharges an excessive process gas and reaction by-products from the reaction chamber;
a heater provided under the susceptor and that heats the wafer to a predetermined temperature;
a radiation thermometer that detects a temperature distribution at least in a circumferential direction at a peripheral edge section of the wafer;
a calculation processing section that determines a presence/absence of adhesion between the wafer and the supporting section based on the temperature distribution detected by the radiation thermometer; and
a temperature control section that controls heating by the heater when a determination that the adhesion is present is made by the calculation processing section, such that a temperature of the wafer during cooling becomes lower than in a case where a determination that the adhesion is absent is made.
